(19) United States
(12) Patent Application Publication
(10) Pub. No.: US 2014/0312371 A1
(43) Pub. Date: Oct. 23, 2014

(54) HYBRID REFLECTOR CUP

(71) Applicant: Avago Technologies General IP (Singapore) Pte. Ltd., (US)

(72) Inventors: Kum Soon Wong, Kuala Lumpur (MY); Kiam Soon Ong, Penang (MY); Keat Chuan Ng, Penang (MY)

(73) Assignee: Avago Technologies General IP (Singapore) Pte. Ltd ., Singapore (SG)

(21) Appl. No.: 13/867,358

(22) Filed: Apr. 22, 2013

(51) Int. Cl. H01L 33/58; F21V 33/00

(52) U.S. Cl. CPC H01L 33/58; F21V 33/0004
USPC 257/98; 362/154

(57) ABSTRACT

A package for a light source and methods of manufacturing the same are disclosed. In particular, a light source package is disclosed with an outer component and an interchangeable inner component. The inner component can be modular and replaceable with other inner components having different properties, thereby enabling a flexible design of a light source package to accommodate different lighting conditions and desired lighting effects.

### FIELD OF THE DISCLOSURE

The present disclosure is generally directed toward light emitting devices and packages for the same.

### BACKGROUND

Light Emitting Diodes (LEDs) have many advantages over conventional light sources, such as incandescent, halogen and fluorescent lamps. These advantages include longer operating life, lower power consumption, and smaller size. Consequently, conventional light sources are increasingly being replaced with LEDs in traditional lighting applications. As an example, LEDs are currently being used in flashlights, camera flashes, traffic signal lights, automotive taillights and display devices.

Currently light source packages utilize a latch-on-lens to produce the desired radiation pattern with a controlled viewing angle. Other design concepts utilize an integrated reflector cup and the dimensions of the reflective cup must be altered to achieve the desired light output.

One disadvantage to the latch-on-lens concept is that it introduces an additional element to the finished product, thereby adding bulk and cost. There is also a strict tolerance control for the lens profile. And, perhaps most importantly, the aesthetics of a latch-on-lens are generally considered less desirable than light source packages having an integrated lens.

The integrated reflector cup also has drawbacks. In particular, a light source package with an integrated reflector cup has limited design freedom and the physical dimensions of the entire package are often constrained by the selected reflector cup. Additionally, the package becomes more costly and is of substantially no use to those that do not need a reflector cup.

### SUMMARY

It is with respect to the above-noted shortcomings that embodiments of the present disclosure were developed. Specifically, embodiments of the present disclosure provide a light source package with an interchangeable inner component that greatly enhances the design opportunities for the light source package. The light source package disclosed herein is less bulky than the latch-on-lens packages and is less costly than packages having an integrated reflector cup.

One advantage of the present disclosure is that the light source package can be individually optimized for any use-case. In other words, the design flexibility offered by embodiments of the present disclosure is greatly increased. In particular, the hybrid nature of the disclosed light source package can accommodate the various viewing angle requirements for any environment.

In some embodiments, the light source package includes a hybrid reflector cup cum lenses concept. The approach is to introduce an inner component, which has had the flexibility of changing its refractive index. In some embodiments, the creation and customization of the inner component can be achieved through injection molding of epoxy and/or silicone. The inner component can then be ‘laminated’ by an outer component. This outer component, in some embodiments, can be of black or white polymer, such as Polyphthalamide (PPA), or a similar thermoplastic synthetic resin of the polyamide family. This outer component, in addition to providing structural protection to the inner component and other parts of the light source package, can function to block light rays from penetrating or passing through. The outer component can also be designed to enhance the contrast when a black or dark material is used.

In some embodiments, the light source package may also be designed to provide an air gap between the inner component and the outer component. In some embodiments, the air gap between the inner and outer components can act as a ‘mirror’ wall to the rays emitted by the light source. This reflection by the air gap occurs because when light passes from a material of a high refractive index (e.g., inner component, n>1) to a material of a lower index (e.g., air, n=1), then internal refraction will occur. This design proposed herein greatly improves the reflector cup's reflectivity compared to prior art designs which only diffuse the light instead of reflecting the light. Of particular note is that the average viewing angle of the light source package can also be narrowed (e.g., controlled) by providing an air gap between the inner component and the outer component. Table 1 below shows the viewing angle differences between a light source package designed in accordance with embodiments of the present disclosure as compared to traditional packages:

TABLE 1
Air Gap vs. Non-Air-Gap Viewing Angle Differences
Average Viewing Angle

| | Air | Non Air |
|---|---|---|
| | gap | gap |
| Blue | 90.3 | 107.6 |
| Green | 97.9 | 111.8 |
| Red | 98.8 | 110.2 |

In addition to the introduction of an air gap, embodiments of the present disclosure also provide an inner component that is interchangeable with other inner components, thereby further increasing the design freedom offered by the light source package. Interchangeable inner components enable the light source package to have different inner components with different refractive indices (RI). By having the changeable RI feature, the inner component can be selected to best compliment the type of light that is being emitted by the light source (e.g., different wavelengths of light may interact optimally with different inner components). For example, if the emitting light source's lambda is approximately 450 nm, the suitable inner component candidate to be chosen to have a RI of approximately 1.575.

Another aspect of the present disclosure is to provide at least some of the interchangeable inner components with one or more light-shaping elements. Examples of suitable light-shaping elements that can be incorporated into the inner component include, without limitation, Fresnel rings, dome shapes, cavity shapes, textured roughening, etc.

The present disclosure will be further understood from the drawings and the following detailed description. Although this description sets forth specific details, it is understood that certain embodiments of the invention may be practiced without these specific details. It is also understood that in some instances, well-known circuits, components and techniques have not been shown in detail in order to avoid obscuring the understanding of the invention.

### BRIEF DESCRIPTION OF THE DRAWINGS

The present disclosure is described in conjunction with the appended figures:

FIG. 1 is an isometric view of a light source package in accordance with embodiments of the present disclosure;

FIG. 2 is a cross-sectional isometric view of a light source package in accordance with embodiments of the present disclosure;

FIG. 3 is an isometric view of a first internal package component in accordance with embodiments of the present disclosure;

FIG. 4 is an isometric view of a second internal package component in accordance with embodiments of the present disclosure;

FIG. 5 is a cross-sectional view of a third internal package component inserted into an outer package component in accordance with embodiments of the present disclosure;

FIG. 6 is a cross-sectional view of a fourth internal package component inserted into an outer package component in accordance with embodiments of the present disclosure; and

FIG. 7 is a flow diagram depicting a method of manufacturing and using a light source package in accordance with embodiments of the present disclosure.

### DETAILED DESCRIPTION

The ensuing description provides embodiments only, and is not intended to limit the scope, applicability, or configuration of the claims. Rather, the ensuing description will provide those skilled in the art with an enabling description for implementing the described embodiments. It being understood that various changes may be made in the function and arrangement of elements without departing from the spirit and scope of the appended claims.

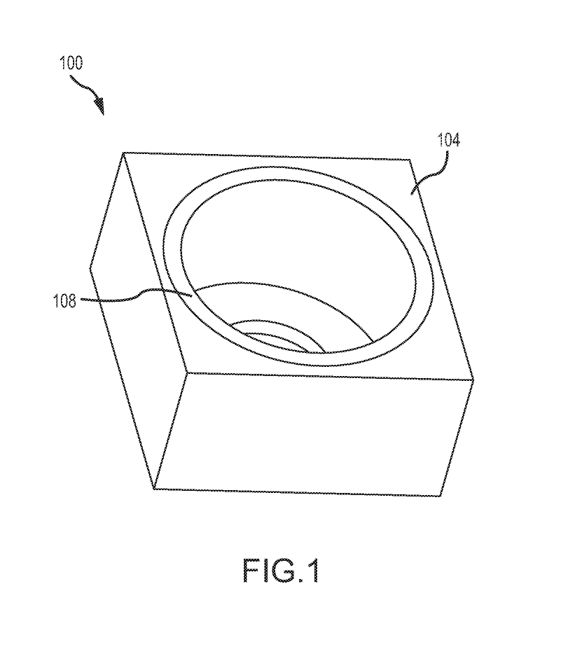

As can be seen in FIGS. 1-6, a package for a light source and various component parts of the same are depicted. As will be described herein, although a particular configuration of package is depicted and described, those of ordinary skill in the art will appreciate that embodiments of the present disclosure are not limited to any particular type of package configuration. In particular, principles discussed herein may be applied in various combinations. Accordingly, although a light source package having a particular configuration is described herein, it should be appreciated that embodiments of the present disclosure are not so limited.

FIG. 1 depicts a light source package 100 in accordance with at least some embodiments of the present disclosure. The light source package 100 is shown to include an outer component 104 and an inner component 108. As will be discussed in further detail herein, the inner component 108 may be interchangeable with other inner components 108 that have similar or different light-shaping properties, refractive indices, or combinations thereof.

In some embodiments, the outer component 104 and/or inner component 108 can be manufactured with injection molding techniques. Specifically, the outer component 104 may be constructed of any polymer or combination of polymers using extrusion, machining, micro-machining, molding, injection molding, or a combination of such manufacturing techniques. As a non-limiting example, the inner component 104 may comprise PPA (black or white), other polymers, ceramics, metal alloys, or combinations thereof.

The inner component 108 may be manufactured of epoxy, silicone, a hybrid of silicone and epoxy, phosphor, a hybrid of phosphor and silicone, an amorphous polyamide resin or fluorocarbon, glass, plastic, or combinations thereof. As with the outer component 104, the inner component 108 may be constructed using any known technique such as extrusion, machining, micro-machining, molding, injection molding, or a combination thereof. In some embodiments, the material used for the inner component 108 may be matched specifically to the light that is emitted by the light source package 100. For instance, the material used for the inner component 108 may be selected based, at least in part, on the wavelength of light emitted by a light source contained in the light source package.

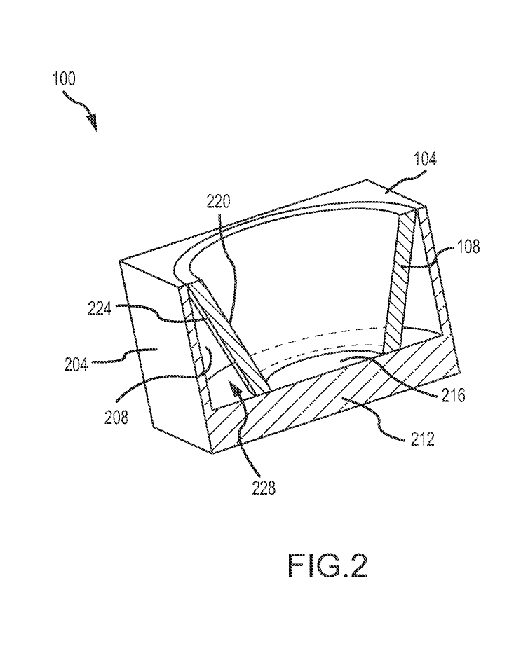

With reference now to FIG. 2, additional details of a light source package 100 will be described in accordance with embodiments of the present disclosure. The outer component 104 is depicted as having a plurality of sidewalls 204 attached to a base 212. In some embodiments, the sidewalls 204 are integrally attached to the base 212 because all parts of the outer component 104 are molded from a single piece of material. Each sidewall 204 may comprise an inner face 208 that faces toward and establishes an inner cavity of the outer component 104. The inner cavity established by the sidewalls 204 and base 212 may be open at its top as light is configured to exit via the opening at the top of the outer component 104. The base 212 may comprise a top surface 216 that is configured to support one or more light sources and/or other electronics. The top surface 216 may also be configured to interface with at least a portion of the inner component 108. As an example, the top surface 216 of the base 212 may provide a structural support for the inner component 108 and/or an interconnection mechanism that enables the inner component 108 to be removably interconnected to the outer component 104.

The inner component 108, in some embodiments, may be conically shaped, thereby enabling the inner component 108 to acts as a reflector cup. The inner component 108 may comprise an inner face 220 and an outer face 224. The inner face 220 of the inner component 108 may also be referred to as the reflective face of the inner component 104 as it corresponds to the first surface that receives light emitted by a light source mounted within the inner component 108. The outer face 224 may be proximate to and face toward the inner face 208 of the sidewalls 204. In some embodiments, a gap 228 is established between the outer face 224 of the inner component 108 and the inner face 208 of the sidewalls 204.

The gap 228 provides a number of advantages and functions. As some examples, the gap 228 may comprise a material or gas therein (e.g., air) with a refractive index that is lower than the refractive index of the material used to construct the inner component 108. By providing the difference in refractive indices at the boundary between the gap 228 and inner component 108, light that is traveling through the material of the inner component 108 to the outer face 224 will be reflected at the boundary. Therefore, most or all of the light that was not reflected by the inner face 220 of the inner component 108 will be reflected by the outer face 224 of the inner component 108. The gap 228 also enables the inner component 108 to interface with the outer component 104 without requiring both components to be built with strict machining tolerances. In other words, the gap 228 enables both components to be built with less restrictive machining tolerances and still interface with one another.

Although most embodiments described herein will refer to the gap 228 being filled with a gas, such as air, it should be appreciated that embodiments of the present disclosure are not so limited. In particular, the gap 228 may be filled with any material that has a lower refractive index that the material of the inner component 108. The material which fills the gap 228 may be solid, liquid, semi-solid, or gas.

It should be appreciated that the inner component 108 may be formed in any uniform or non-uniform shape (e.g., circular, elliptical, trapezoidal, square, rectangular, triangular, etc.) depending upon the desired light distribution. In some embodiments, the area of the inner component 108 is larger its top surface as compared to its bottom surface. This means that the inner component 108 gets larger as it extends away from the base 212.

In some embodiments, the inner face 220 of the inner component 108 is coated with a reflective material. Specifically, the inner face 220 may be coated with a reflective material such as tin, aluminum, etc. to increase the reflectivity of the inner face 220. The reflective material may be deposited on the inner face 220 via any known deposition process such as electroplating, ALD, CVD, magnetron sputtering, and the like.

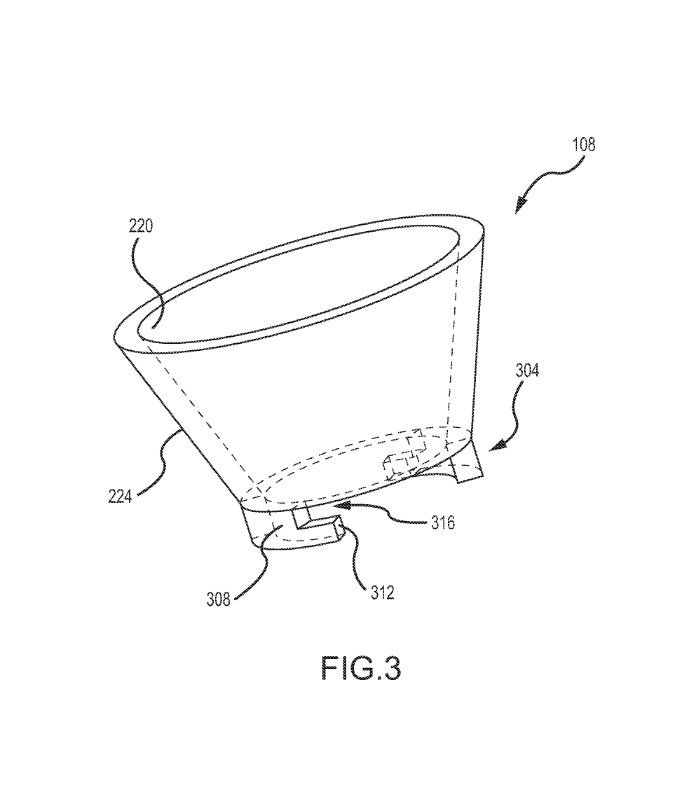

FIG. 3 depicts further details of an illustrative inner component 108 in accordance with embodiments of the present disclosure. The inner component 108 may comprise a bottom portion 304 configured to enable a removable interconnection with the base 212 of the outer component 104. Specifically, the bottom portion 304 of the inner component 108 comprises an extension 308 having one or more hooked tabs 312 with associated notches 316. The extension 308 and hooked tabs 312 may be configured to interface with a female hole or receiving member on the base 212 of the outer component 104. Once inserted, the inner component 108 may be rotated within the outer component 104 to engage the notch 316 with the receiving member on the base 212.

In another embodiment, rather than having hooked tabs 312 and notches 316, the extension 308 may be threaded (female or male threading) and the base 212 may have corresponding threads. The threading of the extension 308 may interface with the threading of the base 212, thereby enabling a friction fitting between the inner component 108 and outer component 104.

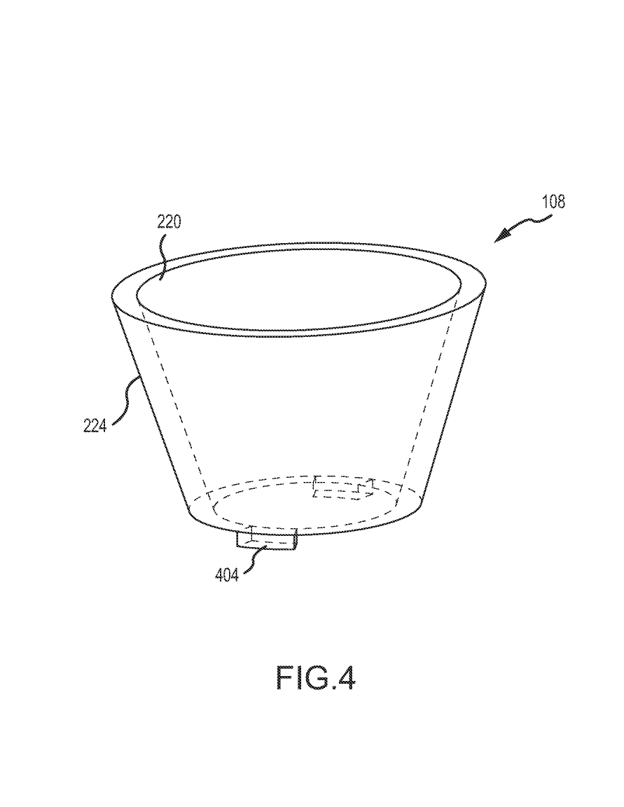

FIG. 4 depicts details of another illustrative inner component 108 in accordance with embodiments of the present disclosure. The inner component 108 depicted in FIG. 4 comprises a straight tab 404 instead of the hooked tab 312 depicted in FIG. 3. The tabs 404 of the inner component 308 can interface with one or more holes or vias in the base 212 of the outer component 104. In some embodiments, an adhesive or epoxy may be used to secure or fix the tab 404 into the base 212 of the outer component 104.

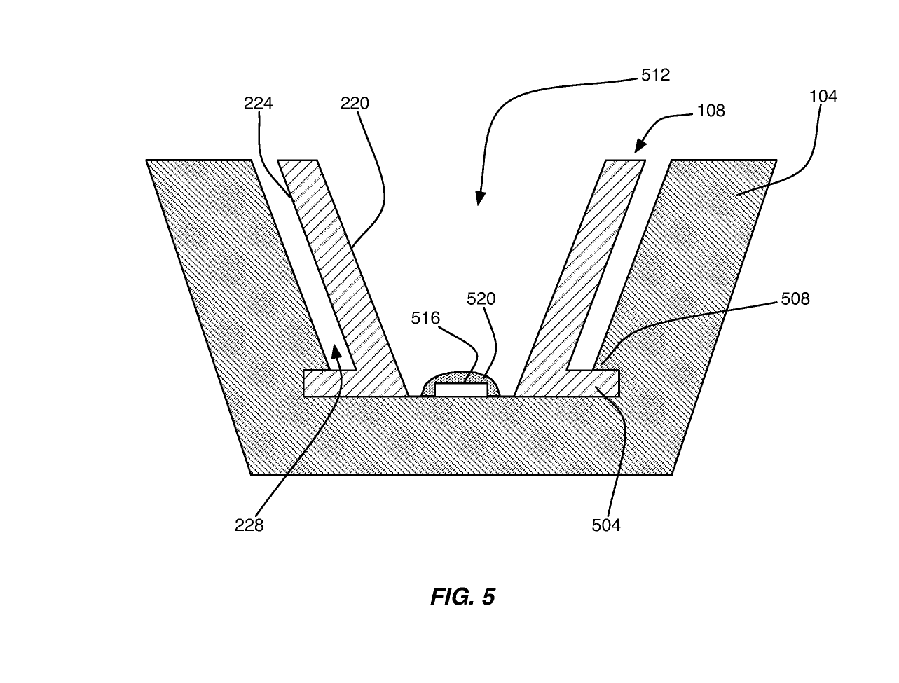

FIG. 5 depicts yet another inner component 108 configuration in accordance with embodiments of the present disclosure. The inner component 108 shown in FIG. 5 exhibits a flange 504 that extends substantially perpendicularly to the major axis of the inner component 108. The flange 504 may completely circumvent the bottom of the inner component 108 or the inner component 108 may have a plurality of flanges that are intermittently separated by space or notches. The flange(s) 504 of the inner component 108 may interface with the outer component 104 at one or more fittings 508. The fittings 508 in the outer component 104 may comprise a notch or recess that receives the flange(s) 504 and secure the inner component 108 to the outer component 104.

FIG. 5 also depicts additional components that may be incorporated in a light source package 100. Specifically, the light source package 100 is shown to include a light source 516 and encapsulant 520. Both the light source 516 and encapsulant 520 are mounted to the top surface 216 of the base 212 within the cavity 512 defined by the inner face 220 of the inner component 108. In some embodiments, the light source 516 may be mounted directly to the top surface 516, one or more wire bonds may be established between a lead frame and the light source, and then some amount of encapsulant 520 may be deposited around the light source 516 and bonding wires to protect those components. In some embodiments, the cavity 512 may be further filled (partially or completely) with another encapsulant material other than encapsulant 520. Any number of materials may be suitable for use as the encapsulant 520. Examples of such materials include, without limitation, epoxy, silicone, a hybrid of silicone and epoxy, phosphor, a hybrid of phosphor and silicone, an amorphous polyamide resin or fluorocarbon, glass, plastic, or combinations thereof. Furthermore, the encapsulant 520 (or the other encapsulant that fills the cavity 512) may be formed to have one or more light-shaping elements (e.g., lens, prism, curved or non-linear feature, etc.) incorporated therein. Specifically, the encapsulant 520 can be formed to have one or more curved surfaces which shape the light emitted by the light source 516 in a desired pattern. As a non-limiting example, the light-shaping element may comprise a dome, a curved surface, a series of curved surfaces, or any other type of surface for directing light in a predetermined direction.

The light source 516, in some embodiments, comprises an LED or array of LEDs. Where an LED or similar light source is used, one bonding wire can be connected to an anode of the light source 516 whereas another bonding wire is connected to a cathode of the light source 516. In some embodiments, the anode and cathode are both on the top light-emitting surface of the light source 516. In some embodiments, the anode and cathode are on opposite surfaces of the light source 516. Such a light source 516 may be constructed using known flip-chip manufacturing processes or any other known method for establishing both an anode and cathode on a common side of a light source 516. In either configuration, by connecting the anode and cathode of the light source 516 to two different conductive leads, an electrical potential can be applied to the anode and cathode of the light source 516 thereby energizing the light source 516 and causing it to emit light. Other suitable light sources include, without limitation, a laser diode, an array of laser diodes, an array of LEDs, or a combination of laser diodes and LEDs.

FIG. 5 also shows a different variation of gap 228 between the inner component 108 and outer component 104. Specifically, the gap 228 depicted in FIG. 5 extends from the flange 504 all the way to the top surface of the inner component 108 and outer component 104, whereas the gap 228 depicted in FIG. 2 does not extend all the way to the top surface of the inner component 108 and outer component 104. Additionally, the gap 228 depicted in FIG. 2 is shown to be larger toward the base 212 and smaller toward the top surface whereas the gap 228 depicted in FIG. 5 is substantially uniform in width along its length.

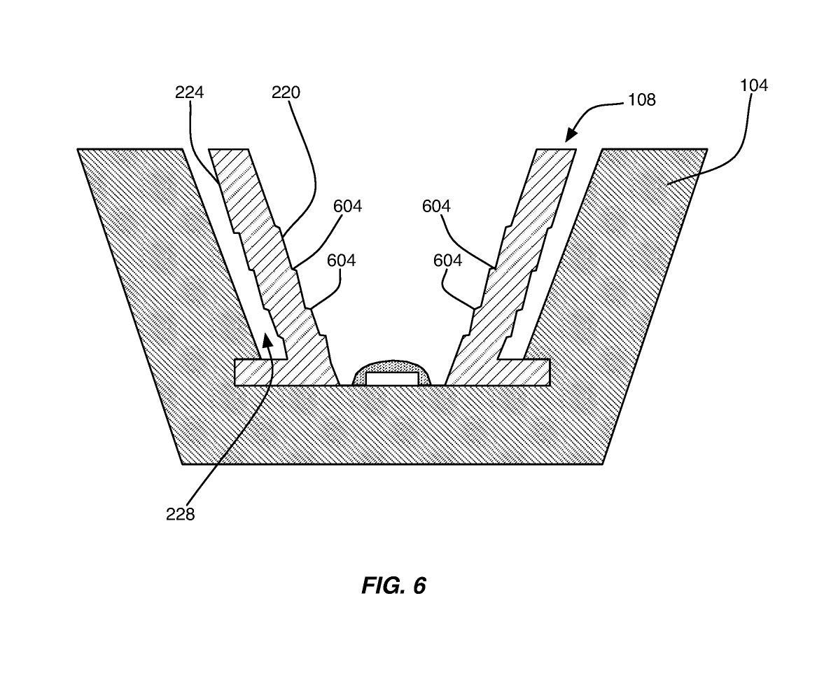

FIG. 6 depicts yet another variant of the inner component 108. In particular, the inner component 108 may include one or more light-shaping elements 604. The light-shaping elements 604 may correspond to any element or combination of elements that are incorporated into the inner component 108 or attached to the inner component 108 that perform some light-shaping function. Examples of light-shaping elements 604 include, without limitation, Fresnel rings, dome shapes, cavity shapes, textured roughening, etc. The light-shaping elements 604 may be disposed concentrically about the inner component 108 with uniform or non-uniform spacing.

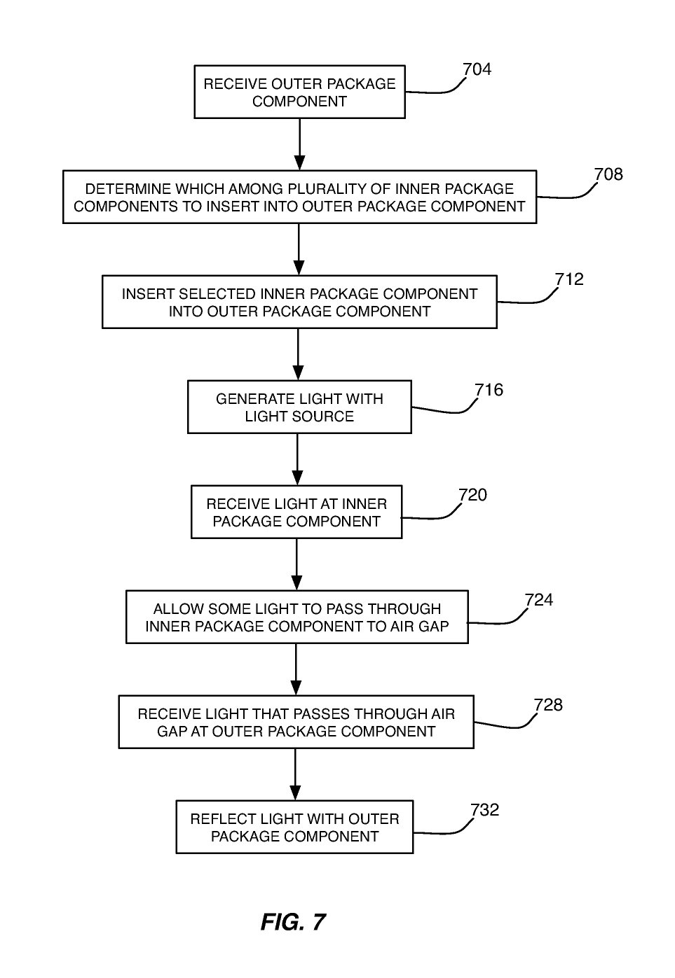

Referring now to FIG. 7, a method of manufacturing and using a light source package 100 will be described in accordance with at least some embodiments of the present disclosure. The method begins with the receipt of the outer component 104 (step 704). Thereafter, a determination is made as to which inner component 108 should be attached to the outer component 104 (step 708). In some embodiments, the determination of the inner component 108 may depend upon the color of light emitted by the light source 516, the desired viewing angle, material within the gap 228, material used for the outer component 104, and/or other considerations.

The selected inner component 108 is then inserted into the outer component 104 (step 712). This step may occur before or after a light source 516 is mounted to the base 212 of the outer component 104. Furthermore, the manner in which the inner component 108 is inserted into the outer component 104 may depend upon the nature of the interface between the components 104, 108. For example, some embodiments may simply rely on a friction or mechanical fit between the two components while other embodiments may utilize an adhesive or epoxy to attach the two components. Other embodiments may utilize magnets or the like to engage the inner component 108 with the outer component 104. Additional manufacturing steps may then be performed, such as filling the cavity 512 of the inner component 108 with an encapsulant or the like.

Once manufactured, the light source package 100 is ready for use. In particular, use of the light source package 100 may involve generating light at the light source 516 (step 716). The light generated at the light source 516 may travel away from the light-emitting surface of the light source through the encapsulant 520 surrounding the light source 520, into the cavity 512 until it eventually reaches the inner component 108 (step 720). In particular, the light generated by the light source 516 is initially received at the inner face 220 of the inner component 108. Depending upon the nature and material provided on the inner face 220, at least some of the light incident on the inner face 220 may be reflected in a direction generally toward the opening of the cavity 512. Still other light may pass into the material of the inner component 108. Specifically, at least some light may be refracted at the inner face 220 when it enters the inner component 108.

The light that passes through the inner face 220 and into the inner component 108 may travel through the material of the inner component 108, which may have an index of refraction greater than 1.00. When the light passing through the inner component 108 reaches the outer face 224 of the inner component 108, some of the light may be reflected at the outer face 224, because the index of refraction of the material in the gap 228 is less than the index of refraction of the material used to construct the inner component 108 (step 724). The light reflected at the outer face 224 may also be directed upward, in the general direction of the opening of the cavity 512.

Although it may be possible to design the inner component 108 to achieve total internal reflection at the outer face 224, it may also be possible that some light passes through the outer face 224. Any light that passes through the outer face 224 may travel through the gap 228 (step 728) until it reaches the outer component 104 where the light can either be absorbed or reflected (step 732). In some embodiments, the outer component 104 may be constructed of a non-reflective material, which means that light passing through the gap 228 may be absorbed by the outer component 104. Still other embodiments contemplate that the inner face 208 of the sidewall 204 may be treated with a reflective material, further enhancing the amount of light output by the light source package 100.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. A light source package, comprising:
an outer component comprising a plurality of sidewalls and a base to which the plurality of sidewalls are connected;
a light source mounted proximate to a top surface of the base such that the light source is at least partially contained within the plurality of sidewalls;
an inner component at least partially contained within the outer component and further surrounding the light source, the inner component comprising one or more inner faces that face toward the light source as well as one or more outer faces that face away from the light source; and
a gap established between the one or more outer faces of the inner component and the plurality of sidewalls of the outer component.

2. The package of claim 1, wherein the gap is at least partially filled with a medium having an index of refraction that is less than an index of refraction of a material used to construct the inner component.

3. The package of claim 2, wherein the gap is at least partially filled with air and wherein the inner component comprises at least one of silicone, epoxy, a hybrid of phosphor and silicone, an amorphous polyamide resin or fluorocarbon, glass, and plastic.

4. The package of claim 3, wherein the outer component comprises a thermoplastic synthetic resin of the polyamide family.

5. The package of claim 2, wherein light which passes through the inner component and reaches the one or more outer faces experiences substantially total internal reflection due to the difference between refractive indices of the medium that at least partially fills the gap and the material used to construct the inner component.

6. The package of claim 1, wherein the gap is substantially uniform in thickness along its length.

7. The package of claim 1, wherein the inner component is interchangeably connected to the outer component.

8. The package of claim 7, wherein the inner component comprises a first interface member that includes at least one of threading, a tab, a hooked tab, and a flange, and wherein the outer component comprises a second interface member that cooperates with the first interface member to enable the interchangeable connection with the inner component.

9. The package of claim 1, wherein the inner component comprises at least one light-shaping element.

10. The package of claim 9, wherein the at least one light-shaping element comprises at least one of Fresnel rings, dome shapes, cavity shapes, and textured roughening.

11. The package of claim 1, wherein the light source comprises a Light Emitting Diode (LED).

12. A package configured to receive a light source, the package comprising:
an outer component comprising one or more sidewalls, a base to which the one or more sidewalls are connected, and an opening that opposes the base;
an inner component at least partially contained within the outer component, the inner component comprising an outer face that substantially faces toward the one or more sidewalls and an inner face that opposes the outer face; and
a gap established between the outer face of the inner component and the one or more sidewalls of the outer component, the gap containing a medium having an index of refraction that is less than a material used to construct the inner component.

13. The package of claim 12, wherein the medium contained in the gap comprises air.

14. The package of claim 13, wherein the material used to construct the inner component comprises at least one of silicone, epoxy, a hybrid of phosphor and silicone, an amorphous polyamide resin or fluorocarbon, glass, and plastic.

15. The package of claim 13, wherein the outer component comprises Polyphthalamide.

16. The package of claim 12, wherein the material used to construct the inner component is selected, at least in part, based on one or more of the following: a wavelength of light to be emitted by the package, a desired viewing angle, and a material used to construct the outer component.

17. The package of claim 12, wherein the inner component comprises at least one light-shaping element and wherein the inner component comprises a conical geometry.

18. A method of operating a light source package comprising an inner component and an outer component, the method comprising:
generating light at a light source;
receiving the light generated by the light source at an inner face of the inner component;
allowing at least some of the light received at the inner face to pass through the inner component;
receiving the light which passes through the inner component at an outer face of the inner component, the outer face being substantially opposed to the inner face and further being proximate to an air gap established between the inner component and outer component; and
reflecting at least some light at the outer face of the inner component.

19. The method of claim 18, wherein the outer face of the inner component substantially reflects all light incident thereon.

20. The method of claim 18, wherein the light reflected by the outer face of the inner component is reflected in substantially a same direction as light reflected by the inner face of the inner component.
